(19) United States
(12) Patent Application Publication
(10) Pub. No.: US 2026/0182455 A1
(43) Pub. Date: Jun. 25, 2026

(54) SEMICONDUCTOR STRUCTURE AND SEMICONDUCTOR PACKAGE

(71) Applicant: TAIWAN SEMICONDUCTOR MANUFACTURING COMPANY LTD., HSINCHU (TW)

(72) Inventors: SHU-WEI CHANG, TAIPEI CITY (TW); CHIA-HUA CHU, HSINCHU COUNTY (TW); SHENG KAI YEH, TAICHUNG CITY (TW); WEI CHUN WANG, TAIPEI CITY (TW); CHENG-CHE TUNG, HSINCHU (TW); CHI-YUAN SHIH, HSINCHU (TW); SHIH-FEN HUANG, HSINCHU COUNTY (TW)

(21) Appl. No.: 18/991,784

(22) Filed: Dec. 23, 2024

(51) Int. Cl. H01L 25/16; G02B 6/42; H01L 23/00; H01L 23/367; H01L 23/528

(52) U.S. Cl. CPC H10W 90/00; G02B 6/4206; H10W 20/435; H10W 40/226; H10W 90/722; H10W 90/792; H10W 90/796

(57) ABSTRACT

A semiconductor structure and a semiconductor package are provided. The semiconductor structure includes a photonic die, a lens, and a heat sink structure. The photonic die includes a grating coupler. The lens is disposed over the grating coupler. The heat sink structure includes a heat sink layer disposed underneath the grating coupler.

### BACKGROUND

Electrical signaling and processing are one technique for signal transmission and processing. Optical signaling and processing have been used in increasingly more applications in recent year. Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure according to one or more embodiments of the present disclosure.

FIG. 2A is a top view of a portion of a semiconductor structure according to one or more embodiments of the present disclosure.

FIG. 2B is a top view of a portion of a semiconductor structure according to one or more embodiments of the present disclosure.

FIG. 2C is a top view of a portion of a semiconductor structure according to one or more embodiments of the present disclosure.

FIG. 2D is a top view of a portion of a semiconductor structure according to one or more embodiments of the present disclosure.

FIG. 2E is a top view of a portion of a semiconductor structure according to one or more embodiments of the present disclosure.

FIG. 2F is a top view of a portion of a semiconductor structure according to one or more embodiments of the present disclosure.

FIG. 3A is a cross-sectional view of a semiconductor structure according to one or more embodiments of the present disclosure.

FIG. 3B is a cross-sectional view of a semiconductor structure according to one or more embodiments of the present disclosure.

FIG. 4A is a cross-sectional view of a semiconductor structure according to one or more embodiments of the present disclosure.

FIG. 4B is a cross-sectional view of a semiconductor structure according to one or more embodiments of the present disclosure.

FIG. 5A is a cross-sectional view of a semiconductor structure according to one or more embodiments of the present disclosure.

FIG. 5B is a perspective view of a semiconductor structure according to one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Embodiments of the present disclosure discuss a semiconductor structure including a heat sink layer underneath a grating coupler which is configured to receive a high-power light. With the above design, the temperature of the grating coupler, when receiving the high-power light, can be reduced. Therefore, the power limit of the input light from the optical source can be increased without causing breakdown of the device.

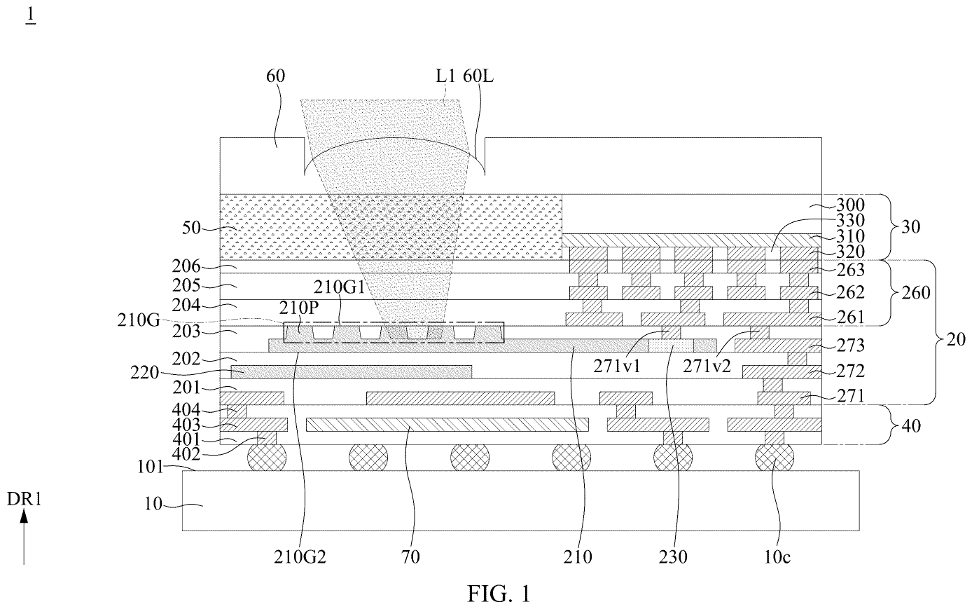

FIG. 1 is a cross-sectional view of a semiconductor structure 1 according to one or more embodiments of the present disclosure. The semiconductor structure 1 may include a substrate 10, electrical connectors 10c, a photonic die 20, an electronic die 30, a redistribution layer 40, a dielectric layer 50, a supporting substrate 60, and a heat sink layer 70. The semiconductor structure 1 may be referred to as a semiconductor package or a partial structure of a semiconductor package. The semiconductor structure 1 may be or include a silicon photonic device.

The substrate 10 may be or include a package component. In some embodiments, the substrate 10 is or includes a package substrate, a printed circuit board, a package, or the like. The substrate 10 may have a top surface 101 for supporting at least the photonic die 20, the electronic die 30, and the redistribution layer 40.

The electrical connectors 10c may be electrically connected to the substrate 10. In some embodiments, the electrical connectors 10c include metal pillars and solder regions, which may be used for solder bonding. In some embodiments, the electrical connectors 10c include solder balls.

The photonic die 20 may be disposed over the top surface 101 of the substrate 10. The photonic die 20 may be referred to as a photonic integrated circuit (PIC) die. In some embodiments, the photonic die 20 includes dielectric layers 201, 202, 203, 204, 205, and 206, conductive features 261, 262, 263, 271, 272, and 273, and components formed in the dielectric layers, such as waveguides 210 and 220, a grating coupler 210G, and a photonic component 230. The photonic die 20 may further include other active or passive components, such as laser diodes, optical signal splitters, or other types of photonic structures or devices.

The waveguides 210 and 220 may be referred to as optical waveguides. The waveguides 210 and 220 may include or be formed of silicon nitride, silicon oxynitride, polymer, or other suitable waveguide materials. In some embodiments, the dielectric layers 201, 202, 203, and 204 that cover the waveguides 210 and 220 are referred to as cladding layers, and the refractive index of the dielectric layers 201, 202, 203, and 204 are smaller than the refractive index of the waveguides 210 and 220 to ensure that the waveguides 210 and 220 have high internal reflections, such that a light L1 coupled from the grating coupler 210G is substantially confined within the waveguides 210 and 220. In some embodiments, the dielectric layers 201, 202, 203, and 204 include silicon oxide, silicon oxynitride, or the like. In some embodiments, the dielectric layers 201, 202, 203, 204, 205, and 206 include silicon oxide, silicon oxynitride, silicon nitride, a polymer, the like, or a combination thereof. In some embodiments, the dielectric layers 201, 202, 203, 204, 205, and 206 include one or more materials (e.g., silicon oxide) that is substantially transparent to the light L1 at wavelengths suitable for transmitting optical signals or optical power from or to the grating coupler 210G. The conductive features 261, 262, 263, 271, 272, and 273 may be or include conductive layers, conductive lines, conductive vias, or the like. The conductive features 261, 262, 263, 271, 272, and 273 may be referred to as electrically conductive layers, electrically conductive lines, and/or electrically conductive vias. The conductive features 261, 262, 263, 271, 272, and 273 may include one or more conductive materials (such as TiN, TaN, Ti, Ta, Cu, W, Co, or the like).

In some embodiments, the grating coupler 210G includes a plurality of protruding lines 210P. In some embodiments, the grating coupler 210G has a coupling surface 210G1 facing upwards and configured to receive the light L1. In some embodiments, the grating coupler 210G has a bottom surface 210G2 opposite to the coupling surface 210G1. In some embodiments, the grating coupler 210G is disposed between the dielectric layers 202, 203, and 204. In some embodiments, the photonic component 230 is formed between the dielectric layers 202 and 203. In some embodiments, the photonic component 230 is optically coupled to the grating coupler 210G. In some embodiments, the waveguide 210 optically couples the photonic component 230 to the grating coupler 210G. The photonic component 230 may include, for example, one or more photonic devices such as photodetectors and/or modulators. For example, a photodetector may be optically coupled to the waveguide 210 to detect optical signals within the waveguide 210 and generate electrical signals corresponding to the optical signals. For example, a modulator may be configured for electrical-to-optical signal modulation and transversion. For example, a modulator may be optically coupled to the waveguides 210 to receive electrical signals and generate corresponding optical signals within the waveguides 210 by modulating optical power within the waveguide 210.

In some embodiments, the conductive features 261, 262, and 263 and portions of the dielectric layers 204, 205, and 206 under the electronic die 30 construct a redistribution layer 260 that electrically connects the photonic die 20 to the electronic die 30. In some embodiments, electrical signals are transmitted between the photonic component 230 and the electronic die 30 through a portion (also referred to as “a first portion”) of the redistribution layer 260. The portion of the redistribution layer 260 may be electrically connected to the photonic component 230 through a conductive via 273v1 of the conductive feature 273.

In some embodiments, the conductive features 271, 272 and 273 are electrically connected to the electronic die 30 through a portion (also referred to as “a second portion”) of the redistribution layer 260. The portion of the redistribution layer 260 may be electrically connected to the conductive feature 273 through a conductive via 273v2. In some embodiments, the conductive features 271, 272, and 273 electrically connect the electronic die 30 to the substrate 10. In some embodiments, a conductive line of the conductive feature 272 and the waveguide 220 are at the same elevation. In some embodiments, a conductive line of the conductive feature 273 and the waveguide 210 are at the same elevation.

The electronic die 30 may be disposed over the photonic die 20. In some embodiments, the electronic die 30 is disposed on and electrically connected to the photonic die 20. The electronic die 30 may be referred to as an electronic integrated circuit (EIC) die. In some embodiments, the electronic die 30 includes a semiconductor substrate 300, an integrated circuit layer 310, electrical connectors 320, and a dielectric layer 330. In some embodiments, the integrated circuit layer 310 is electrically connected to the photonic die 20. In some embodiments, the integrated circuit layer 310 includes integrated circuits, e.g., controllers, drivers, amplifiers, the like, or combinations thereof. The electrical connectors 320 may include conductive pads, conductive pillars, or the like. In some embodiments, the electronic die 30 is bonded to the photonic die 20 through hybrid bonding, direct metal-to-metal bonding, solder bonding, or the like. In some embodiments, when hybrid bonding is adopted, the dielectric layer 330 is bonded to the dielectric layer 206 through fusion bonding, and the electrical connectors 320 are bonded to the conductive features 264 through metal-to-metal direct bonding. The dielectric layers 330 and 206 may include silicon oxide, silicon oxynitride, or the like.

The redistribution layer 40 may be connected to the photonic die 20 and between the photonic die 20 and the substrate 10. In some embodiments, the redistribution layer 40 includes a dielectric structure 401 and conductive features 402, 403, and 404. The conductive features 402, 403, and 404 may be or include conductive layers, conductive lines, conductive vias, or the like. In some embodiments, the redistribution layer 40 electrically connects the photonic die 20 to the substrate 10. The dielectric structure 401 may include a plurality of dielectric layers.

The dielectric layer 50 may be formed over the photonic die 20 and adjacent to the electronic die 30. The dielectric layer 50 may be referred to as a gap-fill material or a gap-fill dielectric. In some embodiments, the dielectric layer 50 is disposed over the grating coupler 210G and at least partially overlapping the heat sink layer 70 in a direction DR1 substantially perpendicular to the top surface 101 of the substrate 10. In some embodiments, the dielectric layer 50 includes silicon oxide, silicon nitride, a polymer, the like, or a combination thereof. In some embodiments, the dielectric layer 50 includes a material (e.g., silicon oxide) that is substantially transparent to the light L1 at wavelengths suitable for transmitting optical signals or optical power from or to the grating coupler 210G.

The supporting substrate 60 may be attached to the electronic die 30 and the dielectric layer 50. In some embodiments, the supporting substrate 60 is a rigid structure that is attached to the electronic die 30 and the dielectric layer 50 in order to provide structural or mechanical stability. In some embodiments, the supporting substrate 60 includes one or more materials such as silicon (e.g., a silicon wafer, bulk silicon, or the like), silicon oxide, metal, an organic core material, the like, or another type of material. The supporting substrate 60 may be referred to as an optical support. In some embodiments, the supporting substrate 60 includes a lens 60L. The lens 60L may be referred to as an optical lens. The lens 60L may be formed by etching the supporting substrate 60. In some embodiments, the lens 60L is disposed over the grating coupler 210G. In some embodiments, the lens 60L is substantially transparent to light L1 at wavelengths suitable for transmitting optical signals or optical power from or to the grating coupler 210G. The light L1 may be focused by the lens 60L to be received by the grating coupler 210G. In some embodiments, a portion of the dielectric layers between the grating coupler 210G and the lens 60L may be substantially free of conductive features or any light-blocking features so as to allow the light L1 to pass through and reach the grating coupler 210G. The above portion may be referred to as an optical path region.

The heat sink layer 70 may be disposed underneath the grating coupler 210G. In some embodiments, the heat sink layer 70 is disposed between the substrate 10 and the grating coupler 210G. In some embodiments, the heat sink layer 70 at least partially overlaps the grating coupler 210G in a direction DR1 substantially perpendicular to the top surface 101 of the substrate 10. In some embodiments, a size (e.g., a radius of a circular layer or a length of a rectangular layer) of the heat sink layer 70 is from about 5 μm to about 50 μm.

In some embodiments, the heat sink layer 70 is within or embedded in the redistribution layer 40. In some embodiments, the dielectric structure 401 and the dielectric layers 201 and 202 collectively construct a dielectric structure that is connected to the bottom surface 210G2 of the grating coupler 210G, and the heat sink layer 70 is embedded in the dielectric structure. In some embodiments, the heat sink layer 70 is between the dielectric layers of the dielectric structure 401. In some embodiments, the heat sink layer 70 and the conductive feature 403 are at the same elevation.

In some embodiments, the waveguide 220 (or the optical waveguide) and the conductive feature 271 (or the electrically conductive layer) are between the heat sink layer 70 and the grating coupler 210G. In some embodiments, the waveguide 220, the conductive feature 271, the dielectric layers 201 and 202, and a portion of the dielectric structure 401 are between the heat sink layer 70 and the grating coupler 210G.

In some embodiments, the heat sink layer 70 includes a material that has a relatively high thermal conductivity. The heat sink layer 70 may include metal, such as TiN, TaN, Ti, Ta, Cu, W, Co, or the like. The heat sink layer 70 may be or include a carbon-containing material, such as a layer of carbon nanotubes, a layer of carbon nanosheets, or the like. In some embodiments, the heat sink layer 70 is or includes a dummy metal pattern that is spaced apart from the grating coupler 210G by a portion (e.g., the dielectric layer 202) of the dielectric structure. The term “dummy metal pattern” refers to a metal pattern that is electrically isolated from the conductive features 261, 262, 263, 271, 272, 273, 402, 403, and 404. The dummy metal pattern is configured transmit heat without transmitting electrical signals. In some embodiments, the heat sink layer 70 and the conductive feature 403 include the same material. In some embodiments, the heat sink layer 70 and the conductive feature 403 are formed by the same process, including the same deposition operation and the same patterning operation.

A high-power optical source (e.g., a high-power laser) may be used for optical communication and optical transmission because it provides an improved signal-to-noise ratio, thus it is beneficial for long-distance transmission. However, when the high-power optical source is used to provide the light L1 including optical signals to the grating coupler 210G, the temperature of the grating coupler 210G may undesirably increase, which may adversely impact the thermal reliability of the grating coupler 210G as well as the semiconductor structure 1.

According to some embodiments of the present disclosure, the heat sink layer 70 is disposed underneath the grating coupler 210G, the temperature of the grating coupler 210G when receiving a high-power light can be reduced. Therefore, the power limit of the input light from the optical source can be increased without causing breakdown of the device. For example, the grating coupler 210G can receive laser light with a power ranging from about 0 dBm up to about 25 dBm and a wavelength ranging from 1260 nm to 1360 nm, and the ambient temperature around the grating coupler 210G can be maintained between about 25° C. and 105° C.

Additionally, for example, simulation results show that a difference in the temperature of the grating coupler 210G with the heat sink layer 70 underneath and the temperature of the grating coupler 210G without the heat sink layer 70 underneath may be up to greater than 105° C. Simulation results also show that the temperature of the grating coupler 210G may be reduced by about 20% with the heat sink layer 70 underneath (e.g., from about 576° C. to about 442° C.) when a copper plate is used as the heat sink layer 70 underneath the grating coupler 210G in the semiconductor structure 1.

In addition, since the light L1 arrives at the grating coupler 210G first followed by transmitting to other structures or device through the waveguide 210, the temperature of the grating coupler 210G is higher than other regions or structures (e.g., the waveguides 210 and 220) of the photonic die 20. According to some embodiments of the present disclosure, the heat sink layer 70 disposed directly underneath the grating coupler 210G is most adjacent to the grating coupler 210G than to other regions or structures (e.g., the waveguides 210 and 220) of the photonic die 20. Therefore, the heat dissipation effect for the photonic die 20 can be improved significantly.

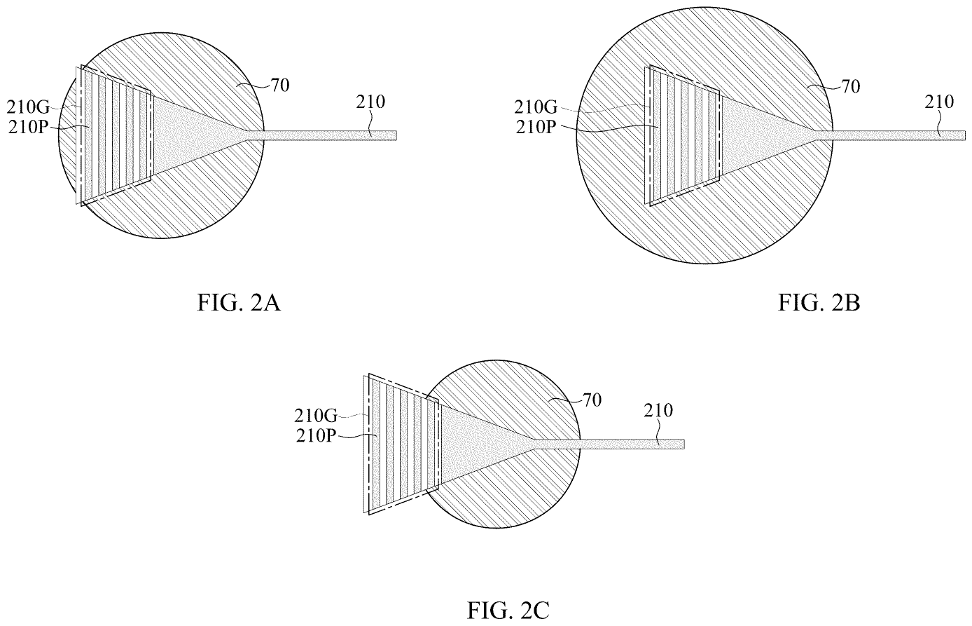

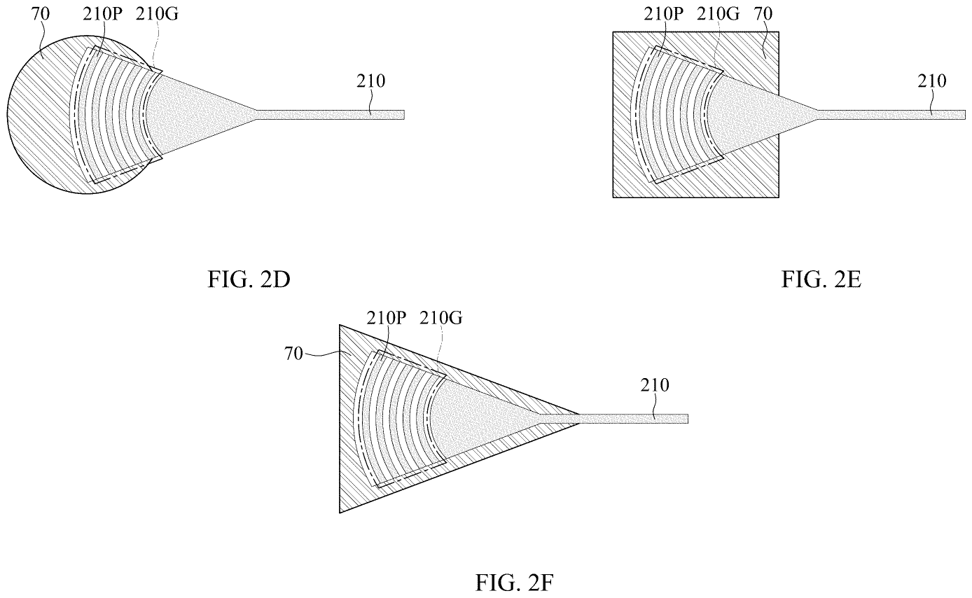

FIG. 2A is a top view of a portion of a semiconductor structure 1 according to one or more embodiments of the present disclosure. In some embodiments, the protruding lines 210P of the grating coupler 210G include substantially straight lines. In some embodiments, the heat sink layer 70 has a circular shape, and the grating coupler 210G has a triangular shape from a top view perspective. In some embodiments, about 90% or higher of a coupling surface of the grating coupler 210G overlaps the heat sink layer 70.

FIG. 2B is a top view of a portion of a semiconductor structure 1 according to one or more embodiments of the present disclosure. In some embodiments, the entire coupling surface of the grating coupler 210G overlaps the heat sink layer 70.

FIG. 2C is a top view of a portion of a semiconductor structure 1 according to one or more embodiments of the present disclosure. In some embodiments, about 20% or lower of a coupling surface of the grating coupler 210G overlaps the heat sink layer 70.

FIG. 2D is a top view of a portion of a semiconductor structure 1 according to one or more embodiments of the present disclosure. In some embodiments, the protruding lines 210P of the grating coupler 210G include curved lines. In some embodiments, about 90% or higher of a coupling surface of the grating coupler 210G overlaps the heat sink layer 70.

FIG. 2E is a top view of a portion of a semiconductor structure 1 according to one or more embodiments of the present disclosure. In some embodiments, the heat sink layer 70 has a rectangular shape from a top view perspective. In some embodiments, the entire coupling surface of the grating coupler 210G overlaps the heat sink layer 70.

FIG. 2F is a top view of a portion of a semiconductor structure 1 according to one or more embodiments of the present disclosure. In some embodiments, the heat sink layer 70 has a triangular shape from a top view perspective. In some embodiments, the entire coupling surface of the grating coupler 210G overlaps the heat sink layer 70.

According to some embodiments of the present disclosure, the size of the heat sink layer 70, the shape of the heat sink layer 70, and the overlapping area of the grating coupler 210G and the heat sink layer 70 may vary according to actual applications. In some embodiments, the greater the overlapping area, the better the heat dissipation effect is.

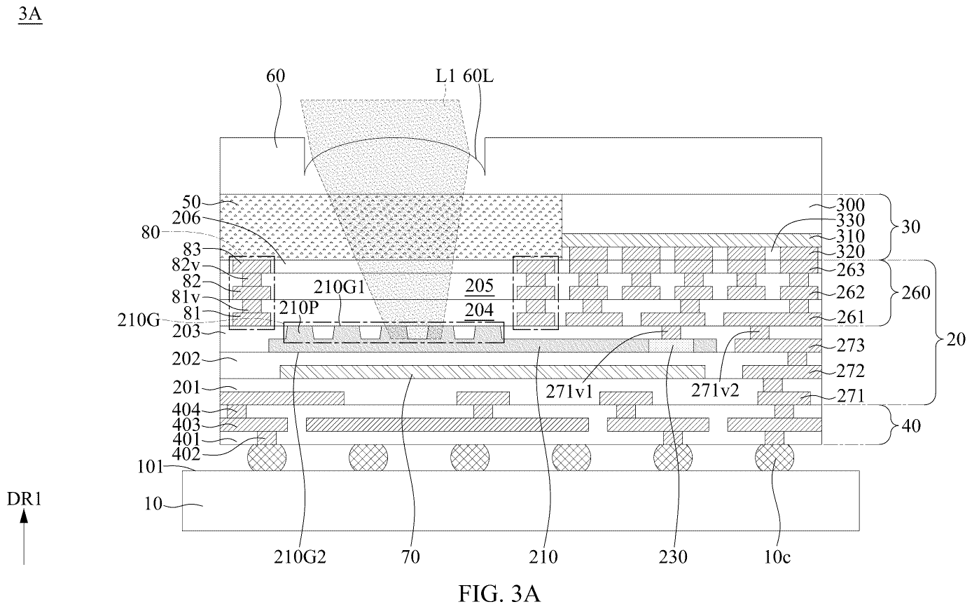

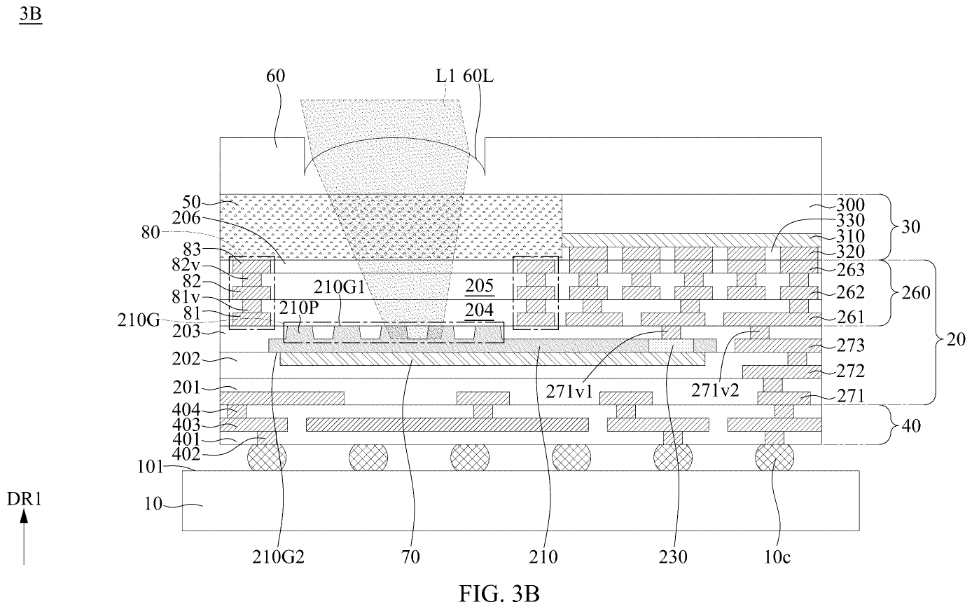

FIG. 3A is a cross-sectional view of a semiconductor structure 3A according to one or more embodiments of the present disclosure. The semiconductor structure 3A may be referred to as a semiconductor package or a partial structure of a semiconductor package. The semiconductor structure 1 may be or include a silicon photonic device. The semiconductor structure 3A illustrated in FIG. 3A is similar to the semiconductor structure 1 illustrated in FIG. 1, and the differences therebetween are described as follows.

In some embodiments, the semiconductor structure 3A further includes an alignment feature 80. The alignment feature 80 includes a guard ring structure. The guard ring structure may surround the optical path region for the light L1. In some embodiments, the alignment feature 80 includes conductive layers 81, 82, and 83 and conductive vias 81v and 82v. In some embodiments, each of the conductive layers 81, 82, and 83 includes a metal ring surrounding the optical path region, and the conductive vias 81v and 82v connect the metal rings. The alignment feature 80 severs to provide an alignment mark during the manufacturing process of the semiconductor structure 1. In some embodiments, the conductive layer 81 and a conductive line of the conductive feature 261 are at the same elevation. In some embodiments, the conductive layer 82 and a conductive line of the conductive feature 262 are at the same elevation. In some embodiments, the conductive layer 83 and a conductive line of the conductive feature 263 are at the same elevation.

In some embodiments, the heat sink layer 70 is further disposed underneath the waveguide 210. In some embodiments, the heat sink layer 70 is further disposed underneath the photonic component 230. In some embodiments, the heat sink layer 70 is within or embedded in the photonic die 20. In some embodiments, the dielectric layer 202 is between and contacts the grating coupler 210G and the heat sink layer 70. In some embodiments, the heat sink layer 70 and a conductive line of the conductive feature 272 are at the same elevation. In some embodiments, the heat sink layer 70 and the conductive line of the conductive feature 272 are formed by the same process, including the same deposition operation and the same patterning operation.

According to some embodiments of the present disclosure, the heat sink layer 70 is integrated into the photonic die 20. Therefore, the distance between the heat sink layer 70 and the grating coupler 210G is reduced significantly, and thus the temperature of the grating coupler 210G is reduced significantly, which increases the thermal stability of the semiconductor structure 3A.

In addition, according to some embodiments of the present disclosure, the heat sink layer 70 is further underneath the photonic component 230. Therefore, it allows for more effective heat dissipation from the photonic component 230 to the heat sink layer 70, thereby effectively reducing the temperature of the grating coupler 210G.

FIG. 3B is a cross-sectional view of a semiconductor structure 3B according to one or more embodiments of the present disclosure. The semiconductor structure 3B may be referred to as a semiconductor package or a partial structure of a semiconductor package. The semiconductor structure 1 may be or include a silicon photonic device. The semiconductor structure 3B illustrated in FIG. 3B is similar to the semiconductor structure 1 illustrated in FIG. 1, and the differences therebetween are described as follows.

In some embodiments, the heat sink layer 70 contacts the bottom surface 210G2 of the grating coupler 210G. In some embodiments, the heat sink layer 70 is or includes an insulating material that contacts the bottom surface 210G2 of the grating coupler 210G. In some embodiments, the heat sink layer 70 includes a carbon-containing material, such as a layer of carbon nanotubes, a layer of carbon nanosheets, or the like. In some embodiments, the heat sink layer 70 includes a material (e.g., silicon oxynitride) having a thermal conductivity greater than that of at least the dielectric layer 202 and having a refractive index smaller than that of the waveguide 210 to ensure the light L1 coupled from the grating coupler 210G is substantially confined within the waveguide 210. The heat sink layer 70 may serve as a heat dissipation element as well as the cladding layer for the waveguide 210. In some embodiments, the heat sink layer 70 and a conductive via of the conductive feature 272 are at the same elevation. The openings or recesses of the dielectric layer 202 for the heat sink layer 70 and the conductive via of the conductive feature 272 may be formed by the same operation.

According to some embodiments of the present disclosure, the heat sink layer 70 is integrated into the photonic die 20 and contacts the grating coupler 210G. Therefore, the heat generated in the grating coupler 210G can be transmitted to the heat sink layer 70 directly without any low-thermal conductivity medium located therebetween. Therefore, the temperature of the grating coupler 210G can be reduced significantly, which significantly increases the thermal stability of the semiconductor structure 3B.

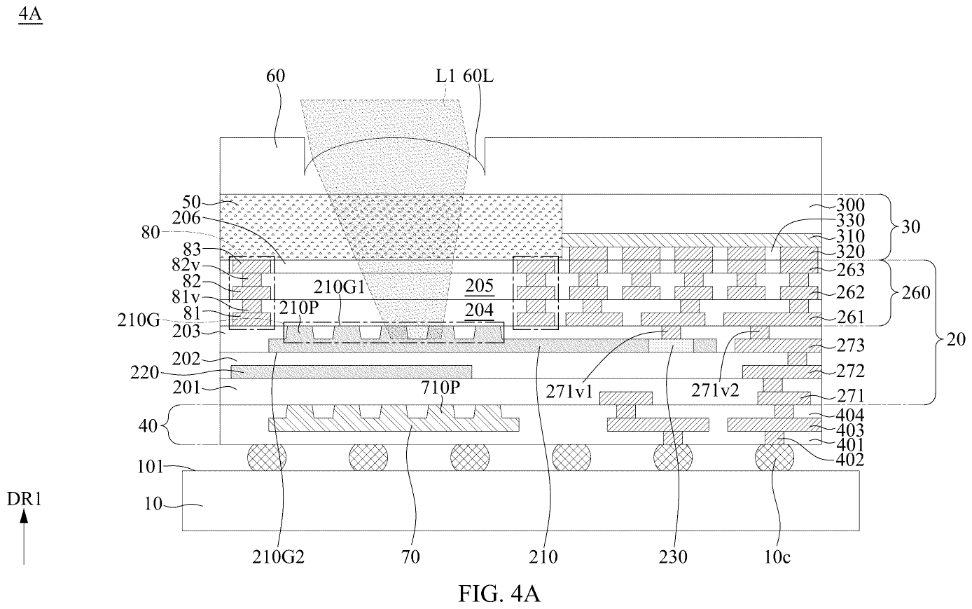

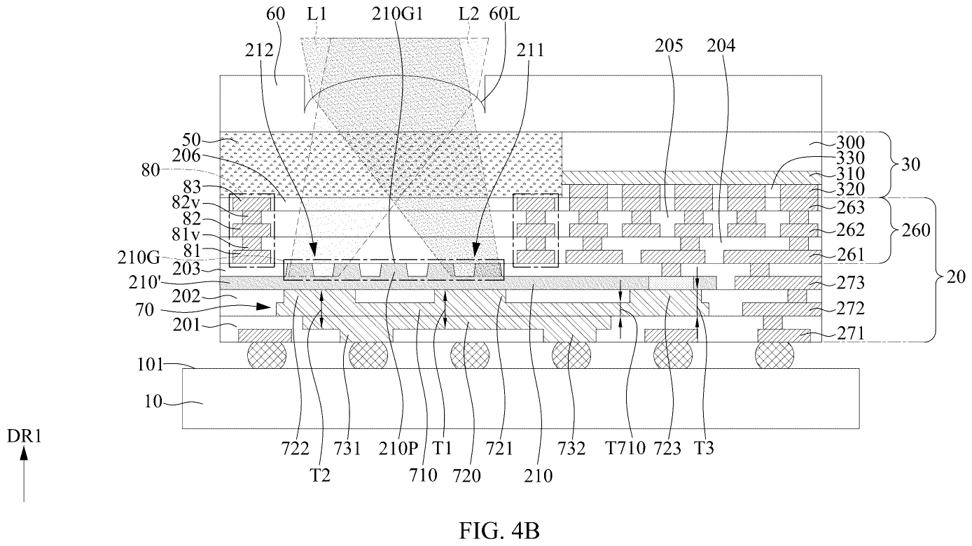

FIG. 4A is a cross-sectional view of a semiconductor structure 4A according to one or more embodiments of the present disclosure. The semiconductor structure 4A may be referred to as a semiconductor package or a partial structure of a semiconductor package. The semiconductor structure 1 may be or include a silicon photonic device. The semiconductor structure 4A illustrated in FIG. 4A is similar to the semiconductor structure 1 illustrated in FIG. 1, and the differences therebetween are described as follows.

In some embodiments, the heat sink layer 70 includes a plurality of protrusions 710P. In some embodiments, the protrusions 710P are disposed underneath and corresponding to the protruding lines 210P of the grating coupler 210G. In some embodiments, the heat sink layer 70 includes a patterned structure substantially the same as that of the grating coupler 210G.

The protruding lines 210P of the grating coupler 210G have relatively large thicknesses, thus more heat may accumulate in the protruding lines 210P. According to some embodiments of the present disclosure, the protrusions 710P of the heat sink layer 70 having relatively large thicknesses and are located directly under each of the protruding lines 210P, respectively. Therefore, it allows for more effective heat dissipation from the protruding lines 210P, thereby effectively reducing the temperature of the grating coupler 210G.

FIG. 4B is a cross-sectional view of a semiconductor structure 4B according to one or more embodiments of the present disclosure. The semiconductor structure 4B may be referred to as a semiconductor package or a partial structure of a semiconductor package. The semiconductor structure 1 may be or include a silicon photonic device. The semiconductor structure 4B illustrated in FIG. 4B is similar to the semiconductor structure 1 illustrated in FIG. 1, and the differences therebetween are described as follows.

In some embodiments, the photonic die 20 further includes a waveguide 210′ optically coupled to the grating coupler 210G. In some embodiments, the waveguide 210′ is configured to transmit optical signals or optical power from or to the grating coupler 210G. In some embodiments, the waveguide 210 and the waveguide 210′ are configured to optically couple the grating coupler 210G to different structures or devices. In some embodiments, the waveguide 210′ optically couples the grating coupler 210G to a component (e.g., laser diodes, optical signal splitters, or other types of photonic structures or devices which are not shown in FIG. 4B) at a side of the grating coupler 210G opposite to the photonic component 230.

In some embodiments, the grating coupler 210G is configured to receive multiple light beams (e.g., lights L1 and L2) from different directions. In some embodiments, the light L1 is focused by the lens 60L to be received by a portion 211 of the grating coupler 210G, and the light L2 is focused by the lens 60L to be received by a portion 212 of the grating coupler 210G. In some embodiments, the portion 211 of the grating coupler 210G is optically coupled to the waveguide 210, and the portion 212 of the grating coupler 210G is optically coupled to the waveguide 210′.

In some embodiments, the heat sink layer 70 includes various portions having different thicknesses. In some embodiments, the heat sink layer 70 includes line portions 710 and 720 and protrusions 721, 722, 723, 731, and 731 protruded from the line portions 710 and 720. In some embodiments, the protrusion 721 is underneath the portion 211 of the grating coupler 210G, the protrusion 722 is underneath the portion 212 of the grating coupler 210G, and the protrusion 723 is underneath the photonic component 230. In some embodiments, the protrusions 731 and 732 are connected to the electrical connectors 10c. In some embodiments, the thickness T1 of the protrusion 721, the thickness T2 of the protrusion 722, and the thickness T3 of the protrusion 723 are greater than the thickness T70 of the line portion 710.

In some embodiments, the heat sink layer 70 is or includes an insulating material that contacts the bottom surface 210G2 of the grating coupler 210G. In some embodiments, the heat sink layer 70 includes a carbon-containing material, such as a layer of carbon nanotubes, a layer of carbon nanosheets, or the like. In some embodiments, the heat sink layer 70 includes a material (e.g., silicon oxynitride) having a thermal conductivity greater than that of at least the dielectric layers 201 and 202 and having a refractive index smaller than that of the waveguides 210 and 210′ to ensure the lights L1 and L2 coupled from the grating coupler 210G are substantially confined within the waveguides 210 and 210′, respectively.

In some embodiments, the heat sink layer 70 may be spaced apart from the grating coupler 210G. In some embodiments, the semiconductor structure 4B may include a redistribution layer 40 as illustrated in FIG. 4A, and the heat sink layer 70 is formed or disposed in the redistribution layer 40 and spaced apart from the grating coupler 210G by the dielectric layers 201 and 202. In some embodiments, the heat sink layer 70 is spaced apart from the grating coupler 210G and includes a material that has a relatively high thermal conductivity, such as TiN, TaN, Ti, Ta, Cu, W, Co, or the like.

According to some embodiments of the present disclosure, the protrusions 721 and 722 of the heat sink layer 70 having relatively large thicknesses are located respectively directly under the portions 211 and 212 of the grating coupler 210G that receive the lights L1 and L2 and thus have more accumulated heat than other regions of the grating coupler 210G. Therefore, it allows for more effective heat dissipation from the portions 211 and 212 of the grating coupler 210G, thereby effectively reducing the temperature of the grating coupler 210G.

In addition, according to some embodiments of the present disclosure, the protrusion 723 of the heat sink layer 70 is directly under the photonic component 230. Therefore, it allows for more effective heat dissipation from the photonic component 230, thereby effectively reducing the temperature of the grating coupler 210G.

Furthermore, according to some embodiments of the present disclosure, the protrusions 731 and 732 of the heat sink layer 70 contact the electrical connectors 10c. The electrical connectors 10c can serve as heat dissipation paths that dissipate heat from the heat sink layer 70 toward outside of the semiconductor structure 4B. Therefore, the heat dissipation effect for the semiconductor structure 4B is further improved, and thus the thermal reliability of the device can be improved significantly.

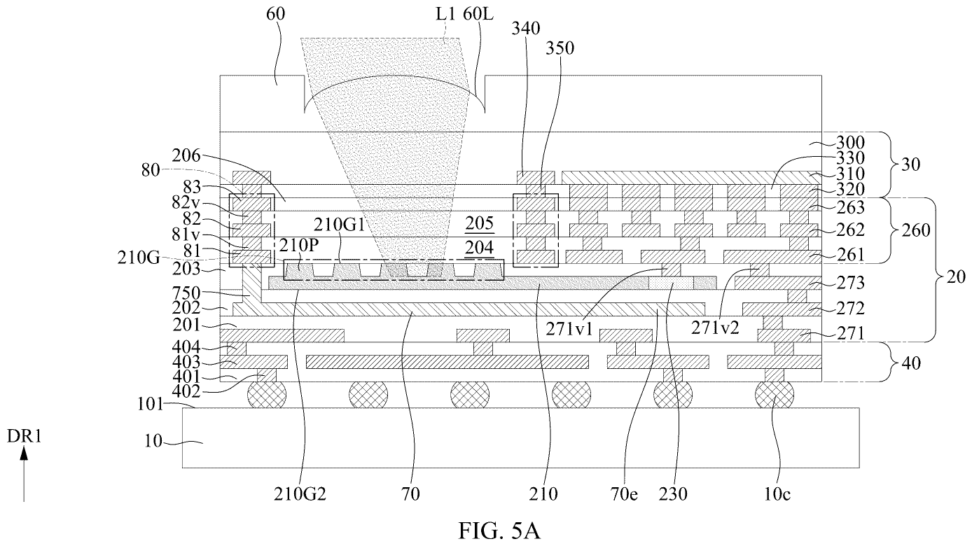

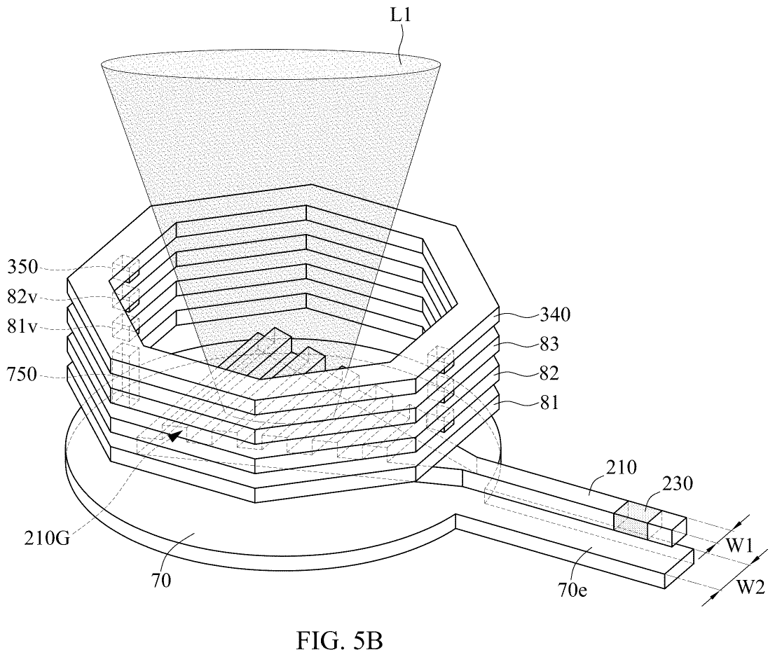

FIG. 5A is a cross-sectional view of a semiconductor structure 5 according to one or more embodiments of the present disclosure. FIG. 5B is a perspective view of a semiconductor structure 5 according to one or more embodiments of the present disclosure. The semiconductor structure 5 may be referred to as a semiconductor package or a partial structure of a semiconductor package. The semiconductor structure 1 may be or include a silicon photonic device. The semiconductor structure 5 illustrated in FIG. 5A and FIG. 5B is similar to the semiconductor structure 1 illustrated in FIG. 1, and the differences therebetween are described as follows.

In some embodiments, the semiconductor structure 5 further includes a pattern 340 and vias 350 over the grating coupler 210G. The pattern 340 may be referred to as a dummy pattern or a heat sink pattern. The vias 350 may be referred to as dummy vias or heat sink vias. In some embodiments, the heat sink layer 70 further includes a pillar 750 connected to the alignment feature 80. The pillar 750 may be referred to as a dummy pillar or a heat sink pillar.

Referring to FIG. 5B, the pillar 750, the alignment feature 80, the pattern 340, and the vias 350 may collectively construct a heat sink wall. In some embodiments, the heat sink wall is partially within the electronic die 30 (e.g., the pattern 340 and the vias 350). In some embodiments, the heat sink wall is partially within the photonic die 20 (e.g., the pillar 750 and the alignment feature 80). In some embodiments, the heat sink wall is free from overlapping the grating coupler 210G in a direction DR1 substantially perpendicular to the coupling surface 210G1 of the grating coupler 210G. The heat sink layer 70, the alignment feature 80, the pattern 340, and the vias 350 may collectively construct a heat sink structure.

In some embodiments, the electronic die 30 extends over the photonic die 20, and the lens 60L is stacked over the electronic die 30. In some embodiments, the pattern 340 is embedded in the electronic die 30. In some embodiments, the pattern 340 is connected to the heat sink layer 70 and free from vertically overlapping the grating coupler 210G. In some embodiments, the pattern 340 includes a metal ring surrounding the optical path region. In some embodiments, the pattern 340 and the integrated circuit layer 310 are at the same elevation. In some embodiments, the pattern 340 is stacked over the conductive layers 81, 82, and 83 of the alignment feature 80.

In some embodiments, the vias 350 are disposed over the photonic die 20. In some embodiments, the vias 350 are embedded in the electronic die 30. In some embodiments, the vias 350 are disposed in the dielectric layer 330. In some embodiments, the vias 350 are connected to the heat sink layer 70 and free from vertically overlapping the grating coupler 210G. In some embodiments, the vias 350 include conductive vias or metal vias surrounding the optical path region. In some embodiments, the vias 350 and the electrical connectors 320 are at the same elevation. In some embodiments, the vias 350 are stacked over the conductive layers 81, 82, and 83 of the alignment feature 80 and connecting the pattern 340 to the alignment feature 80.

In some embodiments, the heat sink layer 70 is further disposed underneath the photonic component 230. In some embodiments, the heat sink layer 70 includes a portion underneath the grating coupler 210G and an extension 70e underneath the waveguide 210 and the photonic component 230. Referring to FIG. 5B, in some embodiments, a width W2 of the extension 70e is substantially equal to or greater than a width W1 of the waveguide 210. In some arrangements, the photonic component 230 entirely overlaps the extension 70e of the heat sink layer 70.

According to some embodiments of the present disclosure, with the design of the heat sink wall, the heat generated on the grating coupler 210G as well as dissipated toward the optical path region above the grating coupler 210G can be dissipated through the heat sink wall. Therefore, the heat dissipation effect for the semiconductor structure 5 is further improved, and thus the thermal reliability of the device can be improved significantly.

In addition, according to some embodiments of the present disclosure, the pattern 340, the vias 350, and the pillar 750 of the heat sink structure can be integrated into the manufacturing processes for forming the photonic die 20 and the electronic die 30. Therefore, not only does it further improve the heat dissipation effect of the semiconductor structure 5, but it also simplifies the manufacturing process of the semiconductor structure 5.

Some embodiments of the present disclosure provide a semiconductor structure. The semiconductor structure includes a photonic die, an electronic die, and a heat sink structure. The photonic die includes a grating coupler. The electronic die is disposed on and connected to the photonic die. The heat sink structure includes a heat sink layer disposed underneath the grating coupler.

Some embodiments of the present disclosure provide a semiconductor package. The semiconductor package includes a substrate, a photonic die, and a heat sink structure. The photonic die is disposed over the substrate and includes a grating coupler. The heat sink structure includes a heat sink layer positioned between the substrate and the grating coupler.

Some embodiments of the present disclosure provide a semiconductor package. The semiconductor package includes a photonic die, an electronic die, and a heat sink structure. The photonic die includes a grating coupler. The electronic die is disposed over the photonic die. The heat sink structure includes a heat sink layer disposed underneath the grating coupler.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a photonic die comprising a grating coupler;
an electronic die disposed on and connected to the photonic die; and
a heat sink structure comprising a heat sink layer disposed underneath the grating coupler.

2. The semiconductor structure of claim 1, further comprising a dielectric structure connected to a bottom surface of the grating coupler, and the heat sink layer is embedded in the dielectric structure.

3. The semiconductor structure of claim 2, wherein the heat sink layer comprises a dummy metal pattern spaced apart from the grating coupler by a portion of the dielectric structure.

4. The semiconductor structure of claim 2, wherein the heat sink layer comprises an insulating material contacting the bottom surface of the grating coupler.

5. The semiconductor structure of claim 1, wherein the photonic die further comprises a photonic component optically coupled to the grating coupler, and the heat sink layer is further underneath the photonic component.

6. The semiconductor structure of claim 1, wherein the grating coupler comprises a plurality of protruding lines, and the heat sink layer comprises a plurality of protrusions disposed underneath and corresponding to the protruding lines of the grating coupler.

7. The semiconductor structure of claim 1, wherein the heat sink structure further comprises a dummy via over the photonic die, wherein the dummy via is connected to the heat sink layer and free from vertically overlapping the grating coupler.

8. A semiconductor package, comprising:
a substrate;
a photonic die disposed over the substrate and comprising a grating coupler; and
a heat sink structure comprising a heat sink layer between the substrate and the grating coupler.

9. The semiconductor package of claim 8, wherein the heat sink layer at least partially overlaps the grating coupler in a direction substantially perpendicular to a top surface of the substrate.

10. The semiconductor package of claim 8, further comprising:
an electronic die disposed on and connected to the photonic die; and
a dielectric layer disposed over the grating coupler and at least partially overlapping the heat sink layer in a direction substantially perpendicular to a top surface of the substrate.

11. The semiconductor package of claim 8, further comprising a redistribution layer electrically connecting the photonic die to the substrate, wherein the heat sink layer is within the redistribution layer.

12. The semiconductor package of claim 11, further comprising an optical waveguide and an electrically conductive layer between the heat sink layer and the grating coupler.

13. The semiconductor package of claim 8, wherein the photonic die comprises a plurality of dielectric layers, and the grating coupler and the heat sink layer are disposed between the dielectric layers.

14. The semiconductor package of claim 8, further comprising an electronic die disposed on the photonic die, wherein the electronic die comprises an integrated circuit layer electrically connected to the photonic die, and the heat sink structure further comprises a heat sink pattern embedded in the electronic die.

15. A semiconductor package, comprising:
a photonic die comprising a grating coupler;
an electronic die disposed over the photonic die; and
a heat sink structure comprising a heat sink layer disposed underneath the grating coupler.

16. The semiconductor package of claim 15, wherein the photonic die further comprises:
a photonic component optically coupled to the grating coupler; and
a redistribution layer electrically connecting the photonic component to the electronic die, wherein the heat sink layer is further disposed underneath the photonic component.

17. The semiconductor package of claim 15, wherein the photonic die further comprises:
a photonic component electrically connected to the electronic die; and
a waveguide optically coupling the photonic component to the grating coupler, wherein the heat sink layer is further disposed underneath the waveguide and the photonic component.

18. The semiconductor package of claim 15, further comprising:
a substrate; and
a redistribution layer between the substrate and the photonic die, wherein the heat sink layer is embedded in the redistribution layer.

19. The semiconductor package of claim 15, further comprising:
a substrate; and
a redistribution layer between the substrate and the photonic die, wherein the heat sink layer is within the photonic die, and the photonic die further comprises a dielectric layer between and contacting the grating coupler and the heat sink layer.

20. The semiconductor package of claim 19, wherein the heat sink structure further comprises a heat sink wall partially within the electronic die and partially within the photonic die, and the heat sink wall is free from overlapping the grating coupler in a direction substantially perpendicular to a coupling surface of the grating coupler.
